(19) United States
(12) Patent Application Publication
(10) Pub. No.: US 2017/0168337 A1
(43) Pub. Date: Jun. 15, 2017

(54) Display Device with Capacitive Coupling Type Touch Panel Input Device

(71) Applicant: Hitachi Chemical Company, Ltd, Chiyoda-ku, Tokyo (JP)

(72) Inventor: Jun TANAKA, Tokyo (JP)

(21) Appl. No.: 15/325,781

(22) PCT Filed: Jul. 2, 2015
(86) PCT No.: PCT/JP2015/069166

§ 371 Date: Jan. 12, 2017

(30) Foreign Application Priority Data
Jul. 15, 2014 (JP) 2014-144900

(51) Int. Cl. G02F 1/1333; H01L 27/32; G02F 1/1343; G02F 1/1335; G06F 3/044; G02F 1/1362

(52) U.S. Cl. CPC G02F 1/13338; G06F 3/044; G02F 1/136286; G02F 1/13439; G02F 1/133504; H01L 27/323; G02F 2001/136295

(57) ABSTRACT

A display device attached with a capacitive coupling type touch panel formed of a transparent conductive film containing metal nanowires as a transparent electrode is exposed to sunlight in an outdoor use and a problem of impairing the reliability of electronic characteristics as an electronic component is solved. As a means for solving the problem, in a display device with a touch panel input device, a structure in which a touch panel substrate is attached to an upper surface of a display device is provided with a light transmission layer that transmits a visible light having a wavelength of 430 nm or more on an upper surface side of the touch panel substrate, or on an upper surface side and a lower surface side of a touch panel, thereby suppressing a light incidence in a wavelength range affecting a metal nanowire conductive film.

### TECHNICAL FIELD

The present invention relates to a display device with a capacitive coupling type touch panel using a metal nanowire conductive film as a transparent electrode as an input device.

### BACKGROUND ART

An active matrix type display device using a thin film transistor has advantages such as thinness and light weight and is generally used as a display device for various electronic devices such as a television, a computer, a cellular phone, a small mobile device, an in-vehicle device, and the like.

Many of those display devices are configured by a liquid crystal display device having a combination of a liquid crystal cell in which a liquid crystal is sandwiched between a pair of transparent substrates, optically anisotropic films that are laminated on both of outer sides of the liquid crystal cell, and a backlight serving as a display light source, or an organic electroluminescence display device in which an organic electroluminescent material is sandwiched between electrodes, and an electric power applied to the electrodes is converted into light emission for spontaneous emission.

Meanwhile, a touch panel is a device having a function of detecting a position by touching a screen corresponding to a display area of the display device with a finger or a pen and inputting position coordinates and the like to the display device by combination with the display device.

There are various methods in an operation principle of the touch panel, but in recent years, a capacitive coupling type touch panel is mainly used for small mobile device applications.

In the capacitive coupling type touch panel, a large number of lattice-patterned transparent electrodes including two vertical and horizontal layers for detecting the touched position are formed on a touch panel screen on a touch panel substrate corresponding to the display device display area. A wire for extracting a position detection signal from a transparent electrode is formed on the periphery of the touch panel screen, and a wiring circuit for outputting a position detection signal to an external detection circuit and the like are provided.

In this method, there is an advantage that a touched position can be detected at high speed, and the position is detected by capturing a change in a capacitance between a fingertip and a position detection electrode based on a finger touch. For example, in the case of detecting X-Y position coordinates, individually, an insulated structure is provided between an X position coordinate detection electrode and a Y position coordinate detection electrode.

In such a touch panel, a metal oxide conductor such as ITO (indium tin oxide) is normally used as the above-described transparent electrode in terms of conductivity and light transmittance. However, since a metal oxide film is usually formed by vacuum deposition through a sputtering method, a formation cost is required. In particular, because a high temperature condition near 200° C. is required to form a film excellent in conductivity and light transmittance with indium tin oxide, there is an advantage that an internal stress of the formed film is large and a stress load is applied to the formed substrate.

A capacitive coupling type touch panel using a conductive film containing metal nanowires instead of such a metal oxide film has been also known. Metal nanowires are conductive fiber materials developed for transparent conductive films with diameters as large as nanometers. In the conductive film containing metal nanowires, the metal nanowires are brought into contact with each other and electrically connected and rendered conductive and exhibit conductivity characteristics. Up to now, the metal nanowires are coated as a coating film It has been known to include a solution in a solution, apply the inkjet method, a dispensing method, a screen printing method and a transparent conductive film on a substrate to form a transparent conductive film In these methods, During film formation, the film shrinks dryly, and the contact junction state between the metal nanowires fluctuates, resulting in individual difference between films. Heretofore, it has been known that metal nanowires are contained in a coating solution, applied onto a substrate by an ink jet method, a dispensing method, and a screen printing method, and dried to from a transparent conductive film. It is conceivable that those methods suffer from a problem that the film is dried and contracted at the time of forming the dried film after the coating time, and a contact junction state between the metal nanowires is fluctuated, and an individual difference occur for each film.

Patent Literature 1 discloses a touch panel that uses a conductive film containing metal nanowires having nonuniformity in conductivity and suppressing variations in the distribution of metal nanowires by forming a transparent electrode made of a conductive film containing the metal nanowires in a transparent resin by film transfer, exposure and development, with the use of a support film provided with a photosensitive resin composition film containing the metal nanowires in the transparent resin.

### CITATION LIST

### Patent Literature

[Patent Literature 1] Japanese Patent Application Laid-Open No. 2014-10516

### SUMMARY OF INVENTION

### Technical Problem

The input device with the capacitive coupling type touch panel is rapidly spread worldwide as an input and display device for a mobile terminal equipment such as a smartphone, a tablet PC and the like and the product shipment quantity is expanding at present. A performance of such a mobile terminal equipment has been improved every year, as a result, of which a power consumption of internal electronic circuit components increases with an increase in processing speed and multifunctionalization, and a calorific value from the circuit components and power supply cells increases. In addition, such a mobile terminal equipment is assumed to be used outdoors as the mobile terminal. For that reason, as an electronic device, a reliability such as an environmental resistance and a durability against a high temperature, a high humidity, an outdoor sunlight, and so on becomes an important issue more than before.

When a conductive film containing the metal nanowires is used as an electrode in the touch panel, the metal nanowires are brought into contact with each other to establish electrical connective conduction and exhibit conductivity characteristics. The touch panel attached to the mobile terminal equipment is exposed to a high temperature, a high humidity environment, and a sunlight incidence under the usage environment described above. In this case, in the case where the metal nanowires are made of a metal or a metal compound which is not inactive except for Au or Pt, if the metal nanowires are exposed to a light under high temperature and high humidity conditions, a problem of impairing the reliability of the electric characteristics as the electronic component due to an influence of the light exposure is found. In the light exposure, not only ultraviolet rays in a solar wavelength range irradiated during outdoor use, but also a short wavelength light in a visible light wavelength range is affected. In addition, a display light entering the touch panel from the display device is affected by the short wavelength light in the visible light wavelength range.

An object of the present invention to provide a display device with a capacitive coupling type touch panel input device using a conductive film containing metal nanowires as an electrode, in particular, a display device with high reliability of electric characteristics.

### Solution to Problem

In order to solve the above problem, according to the present invention, a display device with a capacitive coupling type touch panel input device including a capacitive coupling type touch panel that is provided with a transparent electrode for detecting X-Y position coordinates of a substrate surface on a transparent substrate and detects a touched position of the transparent electrode due to capacitive coupling as an input device, the display device includes: a structure in which a touch panel substrate is bonded to an upper surface of the display device; and a light transmission layer that transmits a visible light having a wavelength of 430 nm or more which is provided on an upper surface side of the touch panel substrate or an upper surface side and a lower surface side of the touch panel.

Moreover, in order to solve the above problem, according to the present invention, in the display device with the capacitive coupling type touch panel input device, a transparent resin of the conductive film is bonded to a surface of the transparent substrate, and the metal nanowires are contained in a thickness of 10 to 200 nm of the surface layer of the conductive film.

Further, in order to solve the above problem, according to the present invention, in the display device with the capacitive coupling type touch panel input device, the transparent resin of the conductive film is formed of a photosensitive resin composition.

Further, in order to solve the above problem, according to the present invention, in the display device with the capacitive coupling type touch panel input device, the light transmission layer is made of an optically transparent resin containing, a light absorption and light scattering reflection material made of a semiconductor compound having a band gap of less than 430 nm in light wavelength.

Further, in order to solve the above problem, according to the present invention, in the display device with the capacitive coupling type touch panel input device, the light transmission layer contains a light absorber made of a compound having a light absorption maximum at a light wavelength of 380 nm or more and less than 430 nm or a material including a molecular structure having a light absorption maximum at a light wavelength of 380 nm or more and less than 430 nm.

### Advantageous Effects of Invention

According to one aspect of the present invention, the display device with the capacitive coupling type touch panel input device that realizes detector of a change in capacitance can be realized with the use of a conductive film of metal nanowires which has a high reliability of an environmental resistance, particularly in electric characteristics.

### BRIEF DESCRIPTION OF DRAWINGS

FIG. 1 is a cross-sectional view illustrating a display device according to a first embodiment of the present invention.

FIG. 2 is a cross-sectional view illustrating an example in which the display device is a liquid crystal display device according to the first embodiment of the present invention.

FIG. 3 is a cross-sectional view illustrating a display device according to a second embodiment of the present invention.

FIG. 4 is a cross-sectional view illustrating a display device according to a third embodiment of the present invention.

FIG. 5 is a cross-sectional view illustrating an example in which the display device is a liquid crystal display device according to the third embodiment of the present invention.

FIG. 6 is a cross-sectional view illustrating a display device according to a fourth embodiment of the present invention.

FIG. 7 is a cross-sectional view illustrating a display device according to a fifth embodiment of the present invention.

FIG. 8 is a top view of a substrate illustrating a capacitive coupling type touch panel according to the present invention.

FIGS. 9A and 9B are an enlarged view and a cross-sectional view illustrating a connection portion of a transparent electrode and a lead wire in a capacitive coupling type touch panel according to the present invention, respectively.

FIGS. 10A and 10B are as enlarged view and a cross-sectional view illustrating an intersection between a connection portion of a transparent electrode for detecting as X-position coordinate and a connection portion of a transparent electrode for detecting a Y-position coordinate.

FIG. 11 is a process diagram illustrating an example of a method of manufacturing the capacitive coupling type touch panel illustrated in FIG. 8.

FIG. 12 is a process diagram illustrating an example of a method of manufacturing the capacitive coupling type touch panel illustrated in FIG. 8 subsequent to FIG. 11.

### DESCRIPTION OF EMBODIMENTS

In order to solve the problem described in a section of the technical problem, in a display device with a touch panel input device, it is important to eliminate an influence of an external light input from an upper surface of a touch panel and a display light input to a back surface of the touch panel from the display device while maintaining a screen display performance as the display device.

Therefore, in order to achieve the above object, a display device with a touch panel input device according to the present invention has a structure in which a touch panel substrate including a capacitive coupling type touch panel that is provided with a transparent trade for detecting X-Y position coordinates disposed on a transparent substrate and detects a touched position of the transparent electrode due to capacitive coupling as an input device is bonded to an upper surface of the display device, and includes a light transmisson layer that transmits a visible light having a wavelength of 430 nm or more which is provided on an upper surface side of the touch panel substrate or an upper surface side and a lower surface side of the touch panel.

In the touch panel, as will be described in detail later, the transparent electrode is made of a conductive film containing metal nanowires in a transparent resin, and is laminated on a partial surface of the conductive film and joined to the metal nanowires exposed from a surface layer of the transparent resin, and is equipped with a connection electrode for connecting a lead wire for connection to an external circuit of the touch panel and the transparent electrode.

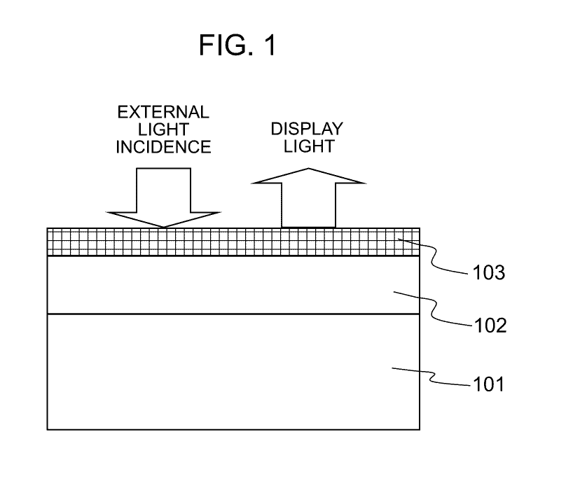

Hereinafter, embodiments of the present invention will be described with reference to FIGS. 1 to 12.

### First Embodiment

FIG. 1 is a cross-sectional view of a display device with a capacitive coupling type touch panel input device according to a first embodiment.

The display device with the capacitive coupling touch panel input device according to the present embodiment includes a capacitive coupling type touch panel 102 on an upper surface of a display device 101, and further includes a specific wavelength range light transmission layer 103 that servers as a light transmission layer for transmitting a visible light having a wavelength of 430 nm or more on an upper surface of the touch panel.

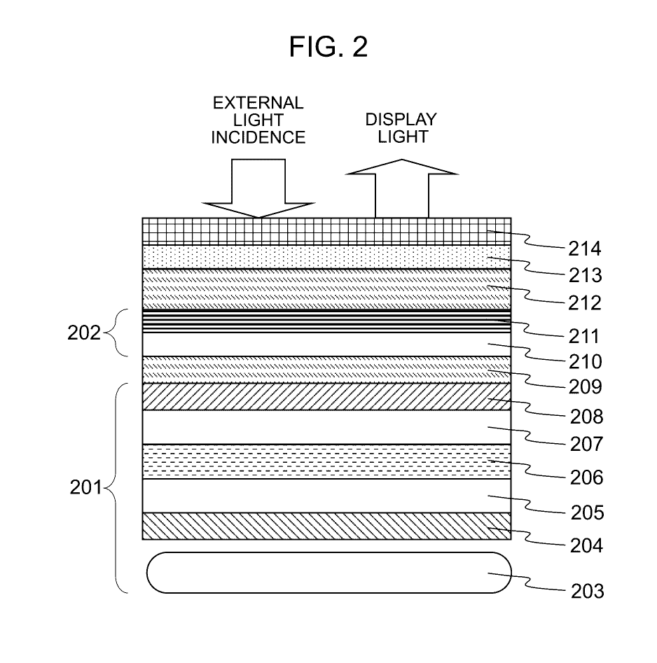

In the present embodiment, an embodiment in which the display device 101 is a liquid crystal display device is illustrated in a sectional view of FIG. 2. In the case where the display device is the liquid crystal display device, a liquid crystal display device 201 has a structure described below. A display circuit which is a pixel assembly of thin film transistor circuits arranged in a matrix is disposed on a first transparent substrate 205, a second transparent substrate 207 is disposed on an opposing surface of the first transparent substrate 205, and a liquid crystal layer 206 is sandwiched between the opposing substrates 205 and 207. Two polarising plates 204 and 208 which are the combination of optically orthogonal states to polarization are disposed outside of the substrates 205 and 207, and light emission in a visible light range from a backlight 203 transmits through the polarizing plate 203 as an image display light through the polarizing plate 204 and the substrate 205.

A capacitive coupling type touch panel 202 (details of the configuration of the touch panel will be described later) is bonded onto an upper surface of the liquid crystal display device 201 through an optically transparent adhesive layer 209. The touch panel 202 is equipped with a touch panel transparent electrode circuit 211 for detecting touch position coordinates on a surface of the touch panel transparent substrate 210.

In the present embodiment, a cover transparent substrate 213 for protect a surface of the touch panel 202 is bonded to an upper surface of the touch panel 202 through an optically transparent adhesive layer 212. A specific wavelength range light transmission layer 214 serving as a light transmission layer for transmitting a visible light having a wavelength of 430 nm or more is disposed on the surface of the cover transparent substrate. In the present embodiment, the light transmission layer 214 is present on the surface of the cover transparent substrate 213. However, on the contrary, the light transmission layer 214 can be disposed in a lower layer, and the cover transparent substrate 213 can be provided on the outermost surface.

In the above embodiment, the liquid crystal display device 201 drives the liquid crystal as an optical shutter, but an FFS (Fringe Field Switching), an IPS (In-Place-Switching), a VA (Vertical Alignment), and a TN (Twisted Nematic) have been known in a liquid crystal drive system, and those techniques can be used.

The transparent substrate 210 of the touch panel 202 is suitably made of, for example, a glass substrate made of alkali glass such as soda glass or borosilicate glass, alkali-free glass, chemically tempered glass or the like. In addition, a polyester film made of polyethylene terephthalate, polyethylene naphthalate, or the like having transparency and a polyimide film with high in heat resistance and transparency have been also known, and such a resin based substrate having transparency can be used.

The light transmission layer 214 that transmits a visible light having a wavelength of 430 nm or more used in the present invention is made of a material film containing semiconductor compound fine particles having a band gap of less than 430 nm in an optically transparent resin, and is suitable for transmitting the visible light having a wavelength of 430 nm or more due to light absorption and light scattering reflection of the semiconductor compound fine particles.

The semiconductor compound fine particles having the band gap of the light wavelength of less than 430 nm suitably includes a main material of SiC fine particles added with compound fine particles selected from ZnO, WO₃, TiO₂, and SrTiO₃. A suitable shape of the fine particles ranges from 10 mm to 100 nm.

The suitable optically transparent resin containing the semiconductor compound fine parties includes a polyolefin resin, a polyester resin, a polyamide resin, a polyimide resin, a polystyrene resin, a polycarbonate resin, an acrylic resin, and so on. More specifically, polyethylene, polypropylene, cyclic polyolefin, polyethylene terephthalate, polyethylene naphthalate, polybutylene terephthalate, polylactic acid, nylon, polycarbonate, polyester carbonate, polymethyl methacrylate, polyethyl methacrylate, and so on are suitable for the optically transparent resin. In the case of the polyimide resin, polyimide having a structure combined with a diphenyl ether skeleton or a biphenyl skeleton as a molecular structure is desirable.

The light transmission layer 214 that transmits the visible light having a wavelength of 430 nm or more used in the present invention includes a light absorption material made of a compound having a light absorption maximum in a light wavelength oil 300 nm or more and less than 430 nm, or contains a material formed of a molecular structure having a light absorption maximum in a light wavelength of 380 nm or more and less than 430 nm. The diameter of the fine particles is suitably in the range oil 10 nm to 100 nm.

As a compound having a light absorption maximum at a light wavelength of 380 nm or more and less than 430 nm, copper halide fine particles, silver fine particles, and so on are suitable. The shape of the fine particles is suitably in a range of 10 nm to 100 nm in diameter.

A polyimide resin having a structure combined with a diphenyl ether skeleton or a biphenyl skeleton as a molecular structure is suitable for a material formed of a molecular structure having a light absorption maximum at a light wavelength of 380 nm or more and less than 430 nm.

In the display device provided with the capacitive coupling type touch panel according to the present invention, the light transmission layer that transmits the visible light having a wavelength of 430 nm or more has a light transmissivity of 50% or more at a wavelength of 430 nm or more.

As the optically transparent adhesive layer 209, a liquid adhesive material is generally called an optically clear adhesive or an adhesive tape is suitable.

As the cover transparent substrate 213, a chemically strengthened glass is suitable.

In the present embodiment, the cover transparent substrate 213 and the specific wavelength region light transmission layer 214 are provided separately. However, fine particles made of SiC, ZnO, WO₃, TiO₂, SrTiO₃, halogenated copper, silver or the like are contained in a chemically strengthened glass to be a cover transparent substrate, thereby being capable of integrating a function of the specific wavelength range light transmission layer with the cover transparent substrate. The shape of the fine particles is suitably in the range of 10 nm to 100 nm in diameter.

### Second Embodiment

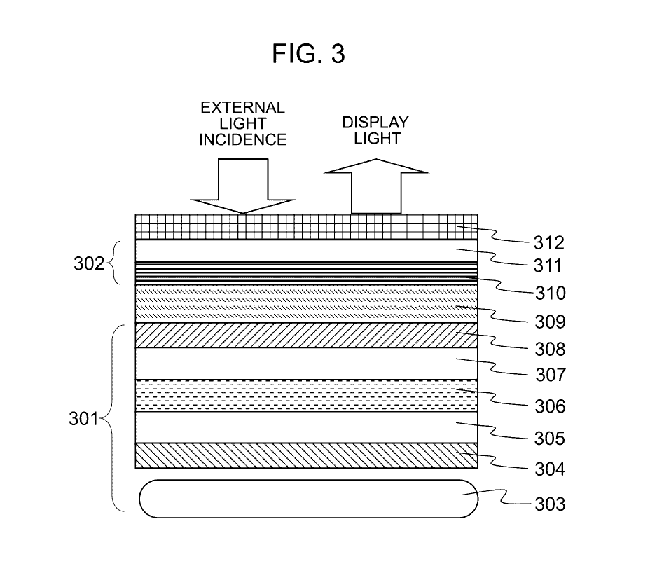

FIG. 3 is a cross-sectional view of a display device with a capacitive coupling touch panel input device according to a second embodiment.

In the display device with the capacitive coupling touch panel input device according to the second embodiment, a capacitive coupling type touch panel 302 is bonded to an upper surface of a light crystal display device 301 through an optically transparent adhesive layer 302. The touch panel 302 includes a touch panel transparent electrode circuit 310 for detecting touch position coordinates on a surface of a touch panel transparent substrate 311.

Furthermore, an upper surface of the touch panel transparent substrate 311 is provided with a second specific wavelength range light transmission layer 312 to be a light transmission layer for transmitting the visible light having a wavelength of 430 nm or more.

In the present embodiment, the touch panel transparent substrate 311 and the specific wavelength range light transmission layer 312 are provided separately. Alternatively, fine particles made of SiC, ZnO, WO₃, TiO₂, SrTiO₃, copper halide, silver, or the like can be contained in a transparent substrate, thereby being capable of integrating the function of the specific wavelength range light transmission layer with the transparent substrate. The shape of the fine particles is suitably in a range of 10 nm to 100 nm in diameter.

In addition, the touch panel transparent substrate 311 can be made of a polyimide resin having a structure combined with a diphenyl ether skeleton or a biphenyl skeleton as a molecular structure, thereby being capable of integrating the function of the specific wavelength range light transmission layer with the transparent substrate.

### Third Embodiment

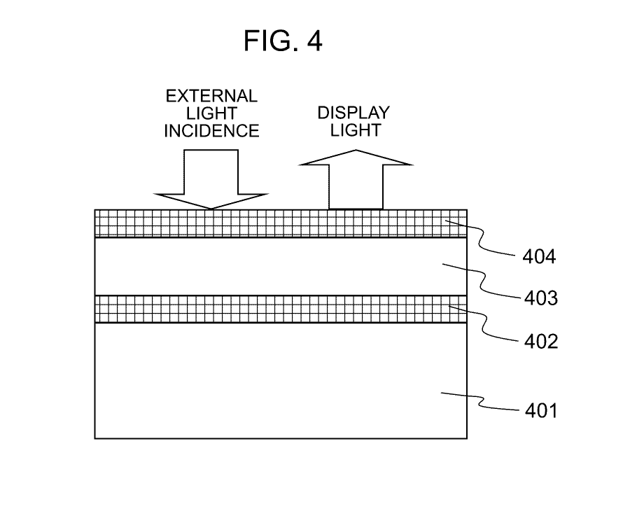

FIG. 4 is a cross-sectional view of a display device with a capacitive coupling touch panel input device according to a third embodiment.

In the display device with the capacitive coupling touch panel input device according to the present embodiment, a first specific wavelength range light transmission layer 402 to be a light transmission layer for transmitting a visible light having a wavelength of 430 nm or more is disposed on an upper surface of the display device 401, a capacitive coupling type touch panel 403 is disposed on an upper surface of the first specific wavelength range light transmission layer 402, and a second specific wavelength range light transmission layer 404 serving as a light transmission layer that transmits the visible light having a wavelength of 430 nm or more is disposed on an upper surface of the touch panel.

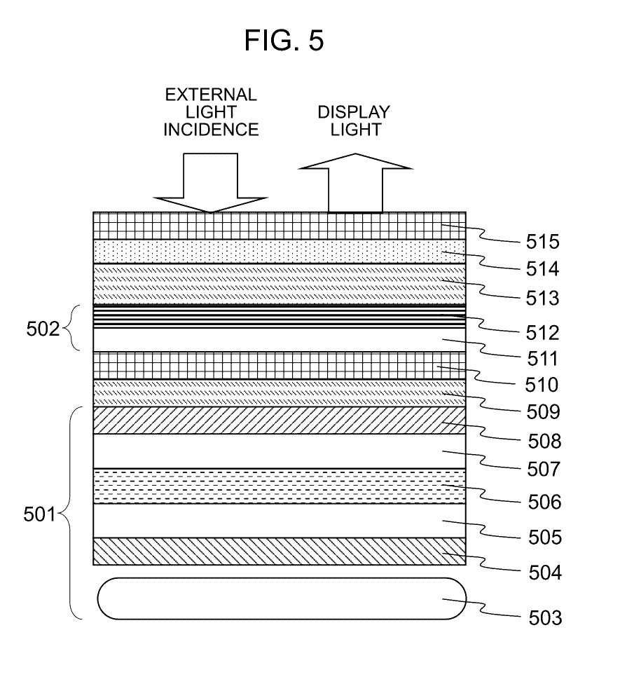

In the present embodiment, an embodiment in which the display device is a liquid crystal display device is illustrated in a cross sectional view of FIG. 5. When the display device is the liquid crystal display device, a liquid crystal display device 501 has a structure described above. In the case where the display device is the liquid crystal display device, a liquid crystal display device 501 has a structure described below. A display circuit which is a pixel assembly of thin film transistor circuits arranged in a matrix is disposed on a first transparent substrate 505, a second transparent substrate 507 is disposed on an opposing surface of the first transparent substrate 505, and a liquid crystal layer 506 is sandwiched between the opposing substrates 505 and 507. Two polarizing plates 504 and 508 which are the combination of optically orthogonal states to polarization are disposed outside of the substrates 505 and 507, and light emission in a visible light range from a backlight 503 transmits through the polarizing plate 508 as an image display light through the polarizing plate 504 and the substrate 505.

An upper surface of the liquid crystal display device 501 is provided with a first specific wavelength range light transmission layer 510 to be a light transmission layer for transmitting the visible light having a wavelength of 430 nm or more through an optically transparent adhesive layer 509, and a capacitive coupling type touch panel 502 disposed on an upper surface of the first specific wavelength range light transmission layer 510.

The touch panel 502 includes a touch panel transparent electrode circuit 512 for detecting touch position coordinates on the surface of the touch panel transparent substrate 511.

In the present embodiment, a cover transparent substrate 514 for protecting a front surface of the touch panel 502 is attached to an upper surface of the touch panel 502 through an optically transparent adhesive layer 513. A second specific wavelength range light transmission layer 515 serving as a light transmission layer for transmitting the light having a wavelength of 430 nm or more is disposed on the surface of the cover transparent substrate.

The light transmisson layer 515 is present on the surface of the cover transparent substrate 514 in the present embodiment. Conversely, the light transmission layer 515 can be disposed in a lower layer, and the cover transparent substrate 514 can be provided on an outermost surface.

In the present embodiment, the cover transparent substrate 514 and the specific wavelength range light transmission layer 515 are provided, separately. Alternatively, fine particles made of SiC, ZnO, WO₃, TiO₂, SrTiO₃, copper halide, silver, or the like can be contained in a chemically strengthened glass to be a cover transparent substrate, thereby being capable of integrating the function of the specific wavelength range light transmission layer with the cover transparent substrate. The shape of the fine particles is suitably in a range of 10 nm to 100 nm in diameter.

In addition, in the present embodiment, the touch panel transparent substrate 511 and the specific wavelength range light transmission layer 510 are provided, separately. Alternatively, fine particles made of SiC, ZnO, WO₃, TiO₂, SrTiO₃, copper halide, silver, or the like can be contained in the transparent substrate, thereby being capable of integrating the function of the specific wavelength range light transmission layer with the transparent substrate. The shape of the fine particles is suitably in a range of 10 nm to 100 nm in diameter.

In addition, the touch panel transparent substrate 511 can be made of a polyimide resin having a structure combined with a diphenyl ether skeleton or a biphenyl skeleton as a molecular structure, thereby being capable of integrating the function of the specific wavelength range light transmission layer with the transparent substrate.

### Fourth Embodiment

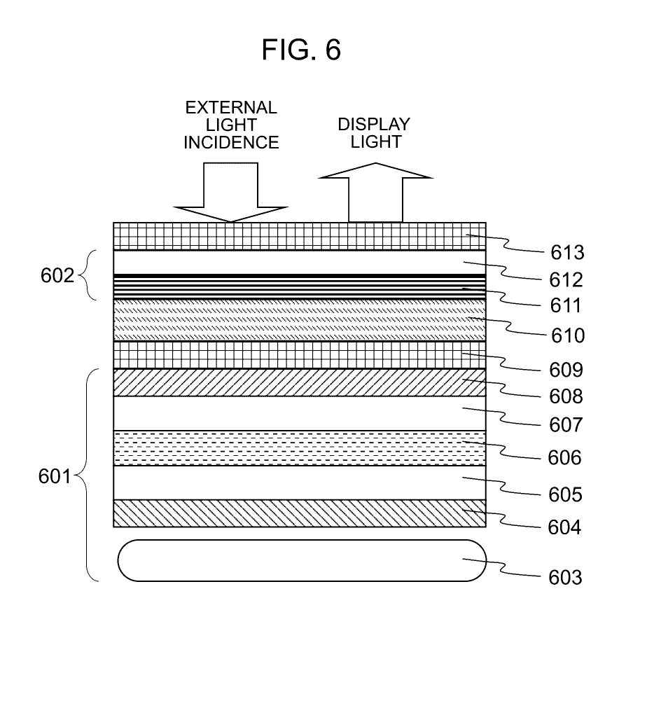

A display device with a capacitive coupling touch panel input device according to a fourth embodiment is illustrated in a cross-sectional view of FIG. 6.

In the display device with the capacitive coupling touch panel input device according to the present embodiment, a first specific wavelength range light transmission layer 609 to be a light transmission layer for transmitting a visible light having a wavelength of 430 nm or more is disposed directly on an upper surface of a liquid display device 601, and a capacitive coupling type touch panel 602 is disposed over the first specific wavelength range light transmission layer 609 through an optically transparent adhesive layer 610. The touch panel 602 includes a touch panel transparent electrode circuit 611 for detecting touch position coordinates on the surface of the touch panel transparent substrate 612.

Further, a second specific wavelength range light transmission layer 613 which is a light transmission layer for transmitting a visible light having a wavelength of 430 nm or more is disposed on an upper surface of the touch panel transparent substrate 612.

### Fifth Embodiment

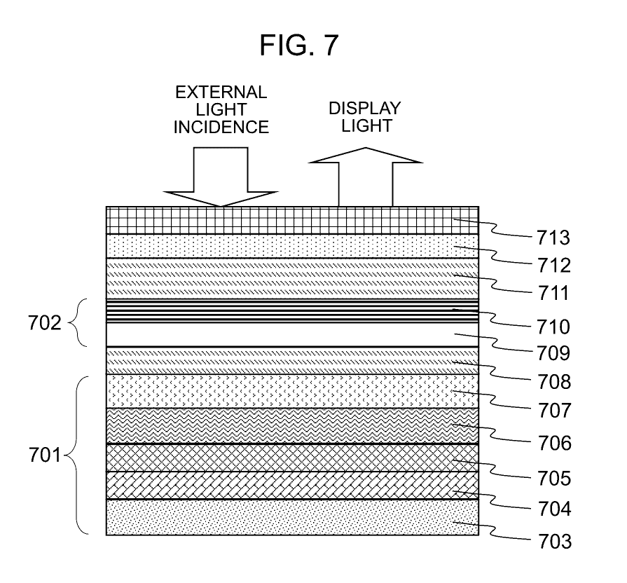

A display device with a capacitive coupling touch panel input device according to fifth embodiment is illustrated in a cross-sectional view of FIG. 7.

The display device with the capacitive coupling type touch panel input device according to the present embodiment includes an organic electroluminescence display device 701. A display circuit layer 704 that is a pixel assembly of a thin film transistor circuit arranged in a matrix is disposed on a first substrate 703 of the display devce 701, and a circuit layer 705 in which an extremely thin film made of an organic electroluminescent material is formed between electrode layers connected to thin film transistor circuits to allow the organic electroluminescent material to emit a light by applying an electric current to the electrodes is disposed on an upper layer of the display layer 704. A transparent substrate 707 bonded to an opposing surface of the substrate 703 with a transparent sealing layer 706 for light transmission seals the opposing surface of the substrate 703 against an external environment. The light emission from the organic electroluminescent light emitting circuit layer 705 passes through a sealing layer 706 and a counter substrate 707 into a display light, to thereby realize the organic electroluminescence display device 701.

A capacitive coupling type touch panel 702 is bonded to an upper surface of the display device 701 through an optically transparent adhesive layer 708. The touch panel 702 includes a touch panel transparent electrode circuit 710 for detecting touch position coordinates on a surface of the touch panel transparent substrate 709. A cover transparent substrate 712 for protecting a surface of the touch panel 702 is bonded to an upper surface of the touch panel 702 through an optically transparent adhesive layer 711. A specific wavelength range light transmission layer 713 to be a light transmission layer that transmits a visible light having a wavelength of 430 nm or more is disposed on the surface of the cover transparent substrate.

Although the light transmission layer 713 is present on the surface of the cover transparent substrate 712 in the present embodiment, the light transmission layer 713 can be provided in a lower layer and the cover transparent substrate 712 can be provided on an outermost surface.

In the present embodiment, the cover transparent substrate 712 and the specific wavelength range light transmission layer 713 are provided, separately. Alternatively, fine particles made of SiC, ZnO, WO₃, TiO₂, SrTiO₃, copper halide, silver, or the like can be contained in a chemically strengthened glass to be a cover transparent substrate, thereby being capable of integrating the function of the specific wavelength range light transmission layer with the cover transparent substrate. The shape of the fine particles is suitably in a range of 10 nm to 100 nm in diameter.

### Sixth Embodiment

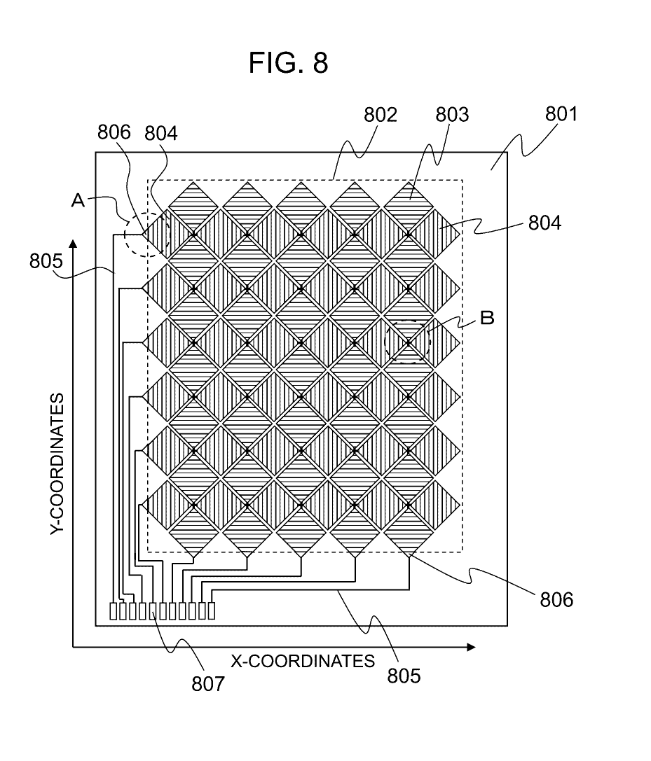

The capacitive coupling type touch panel according to the first to fifth embodiments is illustrated in a top view of the substrate in FIG. 8.

In the touch panel, a touch screen 802 which is an area for detecting touch position coordinates is disposed on one side of a transparent substrate 801, and transparent electrodes 803 and 804 which detect a change in capacitance and output X and Y position coordinates, respectively, are disposed in the area. The transparent electrode 803 for detecting an X position coordinate is connected with the transparent electrodes 803 corresponding to the same X position coordinate, and the transparent electrode 804 for detecting a Y position coordinate is connected with the transparent electrode 804 corresponding to the same Y position coordinate. In those transparent electrodes, lead wires 805 that are connected to element circuits for controlling in electric signals as the touch panel, electrodes 806 for connecting the lead wires to the transparent electrodes, and terminal portions 807 for connection to drive circuit elements are disposed in those transparent electrodes.

A glass substrate such as an alkali glass such as a soda glass and a borosilicate glass, an alkali-free glass, a chemically strengthened glass, or the like is suitable for the transparent substrate 801 used for the touch panel. In addition, a polyester film made of polyethylene terephthalate, polyethylene naphthalate, or the like having transparency and a polyimide film high in heat resistance and transparency have been also known, and such a resin based substrate having transparency can be used.

A metal electrode formed by a sputtering method or a vapor deposition method is suitable for the lead wires 805. More specifically, there are electrodes formed of an alloy such as Ag—Pd—Cu, Al—Cu, Ni—Cu, Al, and Cu, a stacked structure or a single structure. The lead wires 805 can be formed with the use of an Ag conductive paste.

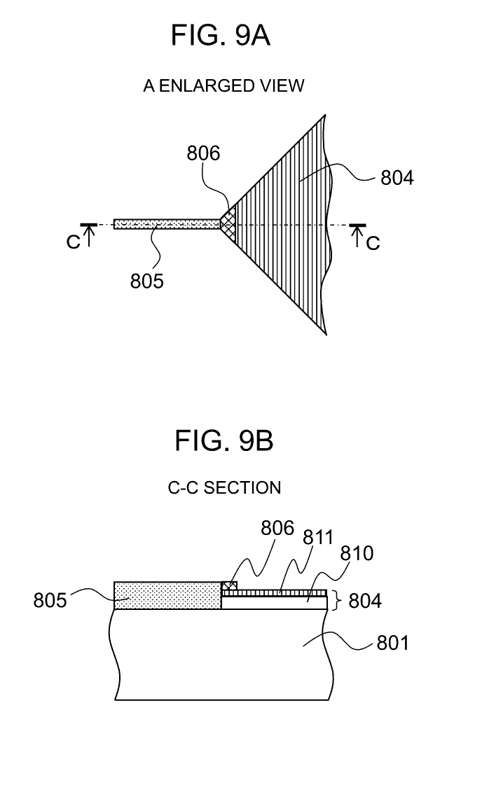

FIGS. 9A and 9B illustrate an A enlarged view and a sectional structure of the connection portion between the lead wire 805 and the transparent electrode 804 outputting the Y position coordinate, respectively.

The electrode 806 connecting the lead wire 805 and the transparent electrode 804 is formed in a structure in which the lead wire 805 is laminated on an end of the transparent electrode 804 when forming the lead wire 805, and more particularly, the electrode 806 does not require a step separate from the lead wire. The respective transparent electrodes 804 corresponding to the same Y position coordinates are connected to each other and connected to the lead wire 805. A cross-sectional structure of the connection portion between the lead wire 805 and the transparent electrode 803 that outputs the X position coordinate is also the same as that described above.

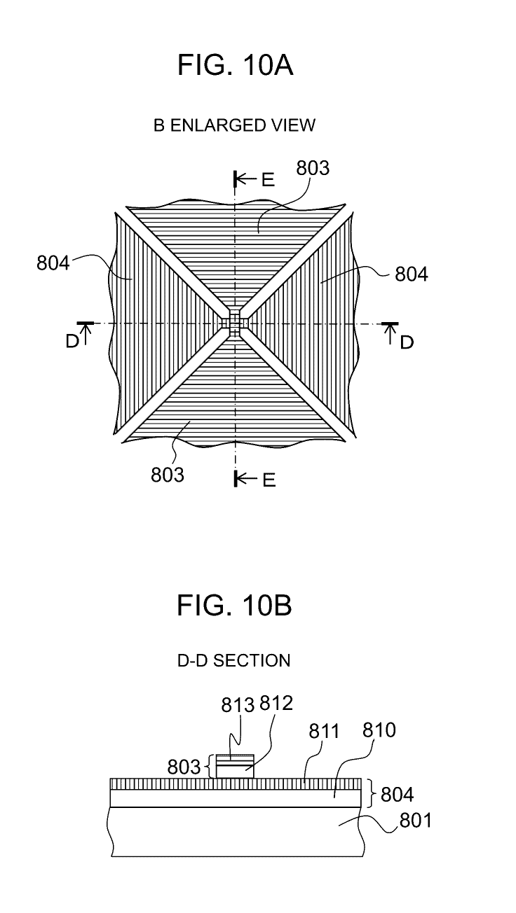

FIGS. 10A and 10B illustrate a B enlarged view and a D-D cross-sectional structure of an intersection of a connection portion of transparent electrodes 803 and 804 corresponding to the X and Y position coordinates, respectively.

An intersection of the connection portion of the transparent electrodes 803 which output the X coordinate with the connection portion of the transparent electrodes 804 which output e position coordinate is insulated from each other by a transparent resin layer 812 made of an insulating resin.

Nanowires made of Ag, Cu, Co, C, Pd, or the like can be used for the metal nanowires contained in the transparent electrodes 803 and 804. Among those materials, Ag nanowires are the most suitable material from the viewpoints of conductivity as the conductive film and light transmittance.

The metal nanowires in the touch panel have a cross-sectional diameter of 10 to 100 nm and a length of 1 to 100 nm.

In addition, in the touch panel, the transparent resins 810 and 812 as conductive films are bonded to the surface of the transparent substrate 801, and the surface layer (811, 813) of the conductive film contains the metal nanowires in a thickness of 10 to 200 nm.

In addition, the metal nanowires may be unevenly distributed to the surface side of the transparent substrate 801 (in a thickness of 10 to 200 nm from the surface).

### Seventh Embodiment

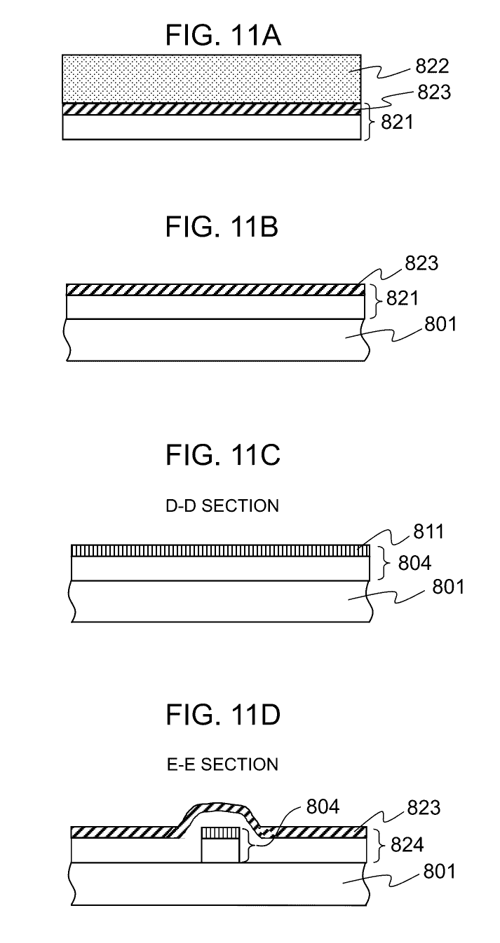

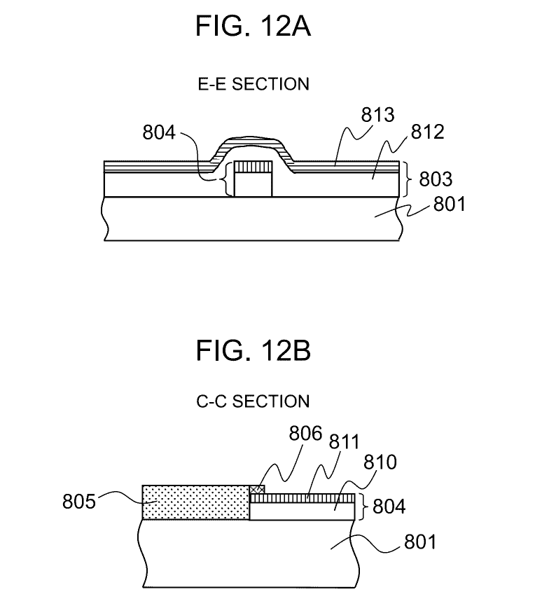

The touch panel of the above sixth embodiment is fabricated under the following conditions in the steps shown in FIGS. 11 and 12.

First, as illustrated in FIG. 11(1), a support film 822 provided with a photosensitive resin composition film 821 containing metal nanowires in a transparent resin (a photosensitive resin composition film disclosed in “WO 2010/10121224” can be used) is prepared. This configuration is a member having a film structure in which the photosensitive resin composition film 821 is laminated on the support film 822 for supporting the photosensitive resin composition film 821. The photosensitive resin composition film 821 includes a metal nanowire containing layer 823.

Next, as illustrated in FIG. 11(2), the photosensitive resin composition film 821 including the metal nanowire containing layer 823 laminated on the support film 822 is bonded to the transparent substrate 801 by film transfer.

Next, as illustrated in FIG. 11(3), the photosensitive resin composition film 821 is exposed into a desired shape through a light shielding mask, an unexposed portion in an exposure step is removed with the use of an alkaline developing solution to form the transparent electrode 804 for outputting the Y position coordinate formed of the conductive film 811 of the metal nanowires contained in the transparent resin 810 formed in the desired shape on the transparent substrate 801.

Next, after the formation of the transparent electrode 804 that outputs the position coordinate, in order to form the transparent electrode 803 that outputs the X position coordinate, as illustrated in FIG. 11 (4), like FIG. 11 (2) described above, the photosensitive resin composition film 824 is again bonded to the transparent substrate 801 by film transfer. FIG. 11 (3) illustrates a D-D cross-section FIG. 10A, and FIG. 11 (4) illustrates an E-E cross-section in FIG. 10A.

Next, as illustrated in FIG. 12 (5), as in FIG. 11 (2) described above, the photosensitive resin composition film is exposed into a desired shape through a light shielding mask, an unexposed portion in an exposure step is removed with the use of an alkaline developing solution to form the transparent electrode 803 for outputting the X position coordinate formed of the conductive film 813 of the metal nanowires contained in the transparent resin 812 formed in the desired shape on the transparent substrate 801.

Next, as illustrated in FIG. 12 (6), a lead wire 805 for connection to an external circuit and a connection electrode 806 for connecting the lead wire 805 and the transparent electrode 804 are formed on the surface of the transparent substrate 801. In this example, the lead wire 805 and the connection electrode 806 are simultaneously formed through a screen printing method with the use of a conductive paste material containing Ag in a flake shape.

A relative positional relationship between the metal nanowires is not varied even after the conductive film has been formed by film transfer, exposure, or development, with the use of the photosensitive resin composition films 821 and 824 in which the metal nanowires are fixed in a solid matter by the transparent resin through the steps (1) to (6) described above. As a result, the capacitive coupling type touch panel having the transparent electrodes 803 and 804 of high-quality X-Y position coordinates can be created, to thereby realize the display device with a capacitive coupling type touch panel input device.

### REFERENCE SIGNS LIST

101 . . . display device, 102 . . . capacitive coupling type touch panel, 103 . . . specific wavelength range light transmission layer,
201 . . . liquid crystal display device, 202 . . . capacitive coupling type touch panel, 203 . . . backlight, 204 . . . polarizing plate, 205 . . . first transparent substrate (thin film transistor circuit substrate), 206 . . . liquid crystal layer, 207 . . . second transparent substrate, 208 . . . polarizing plate, 209 . . . optically transparent adhesive layer, 210 . . . touch panel transparent substrate, 211 . . . touch panel transparent electrode circuit, 212 . . . optically transparent adhesive layer, 213 . . . cover transparent substrate, 214 . . . specific wavelength range light transmission layer,
301 . . . liquid crystal display device, 302 . . . capacitive coupling type touch panel, 303 . . . backlight, 304 . . . a first polarizing plate, 305 . . . first transparent substrate (thin film transistor circuit substrate) , 306 . . . liquid crystal layer, 307 . . . second transparent substrate, 308 . . . second polarizing plate, 309 . . . optically transparent adhesive layer, 310 . . . touch panel transparent electrode circuit, 311 . . . touch panel transparent substrate, 312 . . . specific wavelength range light transmission layer,
401 . . . display device, 402 . . . first specific wavelength band light transmission layer, 403 . . . capacitive coupling type touch panel, 404 . . . second specific wavelength range light transmission layer,
501 . . . liquid crystal display device, 502 . . . capacitive coupling type touch panel, 503 . . . backlight, 504 . . . first polarizing plate, 505 . . . first transparent substrate (thin film transistor circuit substrate), 506 . . . liquid crystal layer, 507 . . . second transparent substrate, 508 . . . second polarzing plate, 509 . . . optically transparent adhesive layer, 510 . . . first specific wavelength range light transmission layer, 511 . . . touch panel transparent substrate, 512 . . . touch panel transparent electrode circuit, 513 . . . optically transparent adhesive layer, 514 . . . cover transparent substrate, 515 . . . second specific wavelength range light transmission layer,
601 . . . liquid crystal display device, 602 . . . capacitive coupling type touch panel, 603 . . . backlight, 604 . . . first polarizing plate, 605 . . . first transparent substrate (thin film transistor circuit substrate), 606 . . . liquid crystal layer, 607 . . . second transparent substrate, 608 . . . second polarizing plate, 609 . . . first specific wavelength range light transmission layer, 610 . . . optically transparent adhesive layer, 611 . . . touch panel transparent electrode circuit, 612 . . . touch panel transparent substrate, 613 . . . second specific wavelength range light transmission layer,
701 . . . organic electroluminescence display device, 702 . . . capacitive coupling type touch panel, 703 . . . first substrate, 704 . . . thin film transistor circuit substrate layer, 705 . . . organic electroluminescent light emitting circuit layer, 706 . . . optically transparent sealing layer, 707 . . . opposed sealing transparent substrate, 708 . . . optically transparent adhesive layer, 709 . . . touch panel transparent substrate, 710 . . . touch panel transparent electrode circuit, 711 . . . optically transparent adhesive layer, 712 . . . cover transparent substrate, 713 . . . specific wavelength range light transmission layer,
801 . . . touch panel transparent substrate, 802 . . . touch screen, 803 . . . capacitive counting detection transparent electrode (X coordinate), 800 . . . capacitive coupling detection transparent electrode (Y coordinate), 805 . . . touch panel circuit connection lead wire, 806 . . . connection electrode between transparent electrode and lead wire, 807 . . . touch panel drive circuit element connection terminal, 810 . . . transparent resin layer of transparent electrode, 811 . . . metal nanowire containing layer or transparent electrode, 812 . . . transparent resin layer of transparent electrode, 813 . . . metal nanowire containing layer of transparent electrode, 821 . . . photosensitive resin composition film containing metal nanowires in transparent resin, 822 . . . support film, 823 . . . metal nanowire containing layer, and 824 . . . photosensitive resin composition film after transfer affixing.

1. A display device with a capacitive coupling type touch panel input device including a capacitive coupling type touch panel that is provided with a transparent electrode for detecting X-Y position coordinates of a substrate surface on a transparent substrate and detects a touched position of the transparent electrode due to capacitive coupling as an input device, the display device comprising:
a structure in which a touch panel substrate is bonded to an upper surface of the display device; and
a light transmission layer that transmits a visible light having a wavelength of 430 nm or more which is provided on an upper surface side of the touch panel substrate or an upper surface side and a lower surface side of the touch panel.

2. The display device with the capacitive coupling type touch panel input device according to claim 1, wherein
in the touch panel, the transparent electrode is made of a conductive film in which metal nanowires are contained in a transparent resin, and
the touch panel includes a connection electrode of a wire which is laminated on a partial surface of the conductive film and joined to the metal nanowires exposed from a surface layer of the transparent resin and led out to an external circuit to output position coordinates of the touch panel.

3. The display device with the capacitive coupling type touch panel input device according to claim 1, wherein
in the touch panel, the transparent electrode is made of a conductive film in which metal nanowires are contained in a transparent resin, and
the metal nanowires have a cross-sectional diameter of 10 to 100 nm and a length of 1 to 100 μm.

4. The display device with the capacitive coupling type touch panel input device according to claim 2, wherein
a transparent resin of the conductive film is bonded to a surface of the transparent substrate, and
the metal nanowires are contained in a thickness of 10 to 200 nm of the surface layer of the conductive film.

5. The display device with the capacitive coupling type touch panel input device according to claim 2, wherein
the metal nanowires are made of a metal other than Au and Pt.

6. The display device with the capacitive coupling type touch panel input device according to claim 2, wherein
the transparent resin of the conductive film is formed of a photosensitive resin composition.

7. The display device with the capacitive coupling type touch panel input device according to claim 3, wherein
a transparent resin of the conductive film is bonded to a surface of the transparent substrate, and
the metal nanowires are contained in a thickness of 10 to 200 nm of the surface layer of the conductive film.

8. The display device with the capacitive coupling type touch panel input device according to claim 3, wherein
the metal nanowires are made of a metal other than Au and Pt.

9. The display device with the capacitive coupling type touch panel input device according to claim 1, wherein
the display device holds a liquid crystal layer between a first transparent substrate and a second transparent substrate arranged to face each other, and includes a backlight that serves as a display light source.

10. The display device with the capacitive coupling type touch panel input device according to claim 1, wherein
the display device is an electroluminescence display device that includes a light emitting element having a first substrate and a second substrate disposed to face each other, and having an organic electroluminescence layer formed on the first substrate between electrode layers, and the light emitting element is sealed hermetically by the second substrate.

11. The display device with the capacitive coupling type touch panel input device according to claim 3, wherein
the transparent resin of the conductive film is formed of a photosensitive resin composition.

12. The display device with the capacitive coupling type touch panel input device according to claim 1, wherein
a light transmissibility at a wavelength of 430 nm or more is 50% or more.

13. The display device with the capacitive coupling type touch panel input device according to claim 1, wherein
the light transmission layer is made of an optically transparent resin containing a light absorption and light scattering reflection material made of a semiconductor compound having a band gap of less than 430 nm in light wavelength.

14. The display device with the capacitive coupling type touch panel input device according to claim 13, wherein
semiconductor compound fine particles having the band gap of a light wavelength of less than 430 nm are obtained by adding fine particles of a compound selected from ZnO, WO₃, TiO₂, and SrTiO₃ with SiC fine particles as a main component.

15. The display device with the capacitive coupling type touch panel input device according to claim 1, wherein
the light transmission layer contains a light absorber made of a compound having a light absorption maximum at a light wavelength of 380 nm or more and less than 430 nm or a material including a molecular structure having a light absorption maximum at a light wavelength of 380 nm or more and less than 430 nm.

16. The display device with the capacitive coupling type touch panel input device according to claim 15, wherein
the compound having the light absorption maximum at the light wavelength of 380 nm or more and less than 430 nm is selected from copper halide fine particles or silver fine particles or a material including the molecular structure having the light absorption maximum at the light wavelength of 380 nm or more and less than 430 nm is selected from a polyimide resin having a diphenyl ether skeleton as a molecular structure or a structure combined with a biphenyl skeleton.
